(19) United States
(12) Patent Application Publication
(10) Pub. No.: US 2004/0182322 A1
(43) Pub. Date: Sep. 23, 2004

(54) WAFER HOLDER FOR SEMICONDUCTOR MANUFACTURING DEVICE AND SEMICONDUCTOR MANUFACTURING DEVICE IN WHICH IT IS INSTALLED

(75) Inventors: Masuhiro Natsuhara, Itami-shi (JP); Hirohiko Nakata, Itami-shi (JP); Manabu Hashikura, Itami-shi (JP)

Correspondence Address: JUDGE PATENT FIRM, RIVIERE SHUKUGAWA 3RD FL., 3-1 WAKAMATSU-CHO, NISHINOMIYA-SHI, HYOGO, 662-0035, JP

(73) Assignee: SUMITOMO ELECTRIC INDUSTRIES, LTD., Osaka-shi (JP)

(21) Appl. No.: 10/604,512

(22) Filed: Jul. 28, 2003

(30) Foreign Application Priority Data
Feb. 6, 2003 (JP) JP-2003-028959

(51) Int. Cl. C23C 16/00

(52) U.S. Cl. 118/728

(57) ABSTRACT

Wafer holder for semiconductor manufacturing and semiconductor manufacturing equipment in which the holder is installed, wherein films may be deposited uniformly over the entire surface of wafers and the generation of particles is slight. In the wafer holder, which has a wafer-carrying surface, the form of an RF power-generating electrode circuit formed in the wafer holder is round, and by making the circuit diameter 90% or more of the diameter of wafers that the wafer holder carries, wafer holders and semiconductor manufacturing equipment with which films whose thickness distribution is uniform are deposited can be realized. Alternatively, rendering the distance between the periphery of the RF-generating electrode circuit and the periphery of the wafer holder longer than the distance separating the electrode circuit from the wafer-carrying surface enables the realization of wafer holders and semiconductor manufacturing equipment wherein the generation of particles is slight.

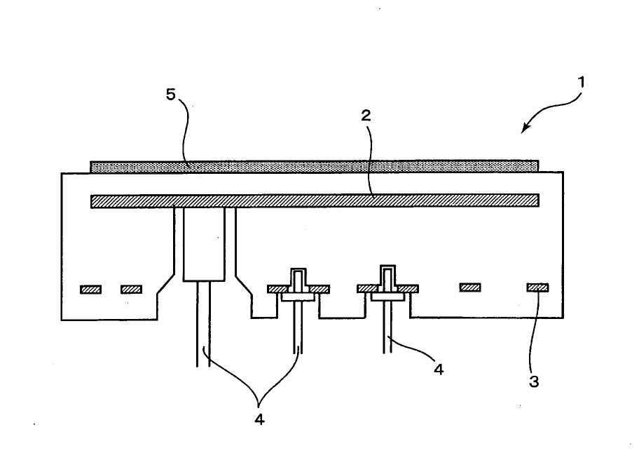

### BACKGROUND OF INVENTION

1. Field of the Invention

The present invention relates to wafer holders employed in semiconductor manufacturing devices such as plasma-assisted CVD, low-pressure CVD, metal CVD, dielectric-film CVD, ion-implantation, etching, Low-K film heat treatment, and degassing heat treatment device; in particular to high-frequency electrode circuits for generating plasma, formed in wafer holders; and furthermore to process chambers and semiconductor manufacturing devices in which the wafer holders are installed.

2. Description of the Background Art

Conventionally, in semiconductor manufacturing procedures various processes such as film deposition processes and etching processes are carried out on semiconductor substrates that are the processed objects. Ceramic susceptors that retain such semiconductor substrates in order to heat them are used in the processing devices in which the processes on the semiconductor substrates are carried out. With ceramic susceptors that in particular are for film-deposition processes in film-deposition equipment, into which reaction gases are introduced, an electrode circuit for generating high-frequency RF power in order to convert the reaction gases into plasma is formed in the ceramic susceptor, separately from the resistive-heating-element circuit for its heater, wherein high-frequency RF power is generated across the RF-generating electrode circuit, and electrode(s) installed on the ceramic susceptor (wafer holder).

Japanese Pat. App. Pub. No. H11-026192 for example discloses a conventional ceramic susceptor of this sort. The ceramic susceptor disclosed in Pat. App. Pub. No. H11-026192 is furnished with a substrate made of an ultrafine ceramic, and electrodes embedded within the substrate; and the minimum separation between the electrodes and the susceptor wafer-retaining face is 0.1 mm or more. More preferably, the minimum separation is 0.5 mm or more and 5 mm or less, and the electrodes are planar electrodes, made from a bulk metal.

In this invention, with the objective of preventing particles from being generated by the substrate reacting with reaction gases introduced into semiconductor manufacturing equipment, the configuration adopted is as just noted. Nevertheless, particles are generated not only by reaction between the reaction gases and substrate; during film deposition a film sometimes forms on, apart from the wafer, the susceptor wafer-retaining face for example, and this will turn into particles.

In recent years, moreover, wafer diameters are being enlarged—from 8 inches to 12 inches in diameter in the case of silicon wafers for example. Consequent on this diametric enlargement of wafers, getting plasma to be generated uniformly on the entire wafer surface has proven to be difficult using conventional wafer holders of the sort described above, and fluctuations in film thickness where film is deposited on the wafer periphery have appeared, which has turned out to be a factor causing yields to drop.

### SUMMARY OF INVENTION

The present invention has been brought about to address the foregoing issues. In particular, an object of the present invention is to realize for semiconductor manufacturing devices a wafer holder with which the deposition of films uniformly over the entire face of wafers is made possible and the generation of particles is slight, and to realize a semiconductor manufacturing device in which the wafer holder is installed.

The present inventors, discovering that the above-stated objective can be accomplished by reexamining the relationship between the diameter of the RF power electrode circuit formed in the wafer holder, and the diameter of the wafers that it carries, arrived at the present invention.

Namely, in the present invention, in a wafer holder having a wafer-carrying surface the form of the high-frequency RF power-generating electrode circuit formed in the wafer holder is round, and its diameter is 90% or more of the diameter of the wafers that the wafer holder carries, and preferably is the diameter of, or greater than that of, the carried wafer. An alternative is that the distance between the periphery of the RF power-generating electrode circuit formed in the wafer holder and the periphery of the wafer holder is longer than the distance separating the electrode circuit from the wafer-carrying surface. A further, preferable alternative is that the electrode circuit is round and its diameter is 90% or more of the diameter of the wafers that are carried, and moreover, the distance between the periphery of the RF power-generating electrode circuit and the periphery of the wafer holder is longer than the distance separating the electrode circuit from the wafer-carrying surface.

With semiconductor manufacturing equipment in which a wafer holder as described above is installed, inasmuch as plasma required for film deposition can be uniformly generated directly, and only directly, onto wafers that are the objects being processed, semiconductors can be manufactured at better yields.

From the following detailed description in conjunction with the accompanying drawings, the foregoing and other objects, features, aspects and advantages of the present invention will become readily apparent to those skilled in the art.

### BRIEF DESCRIPTION OF DRAWINGS

The FIGURE illustrates one example of the sectional structure of a wafer holder according to the present invention.

### DETAILED DESCRIPTION

The present inventors discovered that in order to generate plasma uniformly over an entire wafer surface and to suppress the production of particles, the diameter of a high-frequency RF electrode circuit 2 formed in a wafer holder 1, as illustrated in the FIGURE, ought to be 90% or more of the diameter of a carried wafer 5. It was discovered that because the plasma generated when the diameter of the RF-power electrode circuit is less than 90% of the diameter of the carried wafer turns out not to cover sufficiently the wafer entirety, the thickness of the deposited film tends to thin out along the wafer periphery. In order to make the thickness distribution of the deposited film more uniform, the diameter of the electrode circuit should be made larger than the wafer diameter.

Nevertheless, if the diameter of the RF-power electrode circuit proves to be too large, the wafer-retaining face outward of the wafer-carrying portion of the wafer holder will also end up with film deposited on it. Film formed onto the wafer-retaining face peels off and falls from the wafer holder, turning into particles, when the wafers are handled or when drawing and releasing a vacuum in the process chamber. Scattering within the chamber, the particles stick onto the wafers, which leads to decline in wafer throughput.

Given this situation, it was discovered that by making the distance between the periphery of the RF power-generating electrode circuit and the periphery of the wafer holder longer than the distance separating the electrode circuit from the wafer-carrying surface, the generation of particles as described above can be kept under control. In this way, the density of plasma generated over the wafer holder wafer-retaining face outward of a wafer set in place on the wafer holder is made relatively less compared with the density of plasma generated over the wafer, which significantly thins the thickness of film deposited onto the wafer-retaining face outward of the wafer, whereby the generation of particles as just described can be kept under control.

Insofar as the substances for a wafer holder according to the present invention are insulative ceramics, they are not particularly restricted, but aluminum nitride (AlN) is preferable for its high thermal conductivity and superior corrosion resistance. In the following, a method according to the present invention of manufacturing a wafer holder in a AlN instance will be described in detail.

An AlN raw-material powder whose specific surface area is 2.0 to 5.0 m²/g is preferable. The sinterability of the aluminum nitride declines if the specific surface area is less than 2.0 m²/g. Handling proves to be a problem if on the other hand the specific surface area is over 5.0 m²/g, because the powder coherence becomes extremely strong. Furthermore, the quantity of oxygen contained in the raw-material powder is preferably 2 wt. % or less. In sintered form, its thermal conductivity deteriorates if the oxygen quantity is in excess of 2 wt. %. It is also preferable that the amount of metal impurities contained in the raw-material powder other than aluminum be 2000 ppm or less. The thermal conductivity of the powder in sintered form deteriorates if the amount of metal impurities exceeds this range. In particular, the content respectively of Group IV elements such as Si, and elements of the iron family, such as Fe, which have a serious worsening effect on the thermal conductivity of the sinter, is advisably 500 ppm or less.

Because AlN is not a readily sinterable material, adding a sintering promoter to the AlN raw-material powder is advisable. The sintering promoter added preferably is a rare-earth element compound. Since rare-earth element compounds react with aluminum oxides or aluminum oxynitrides present on the surface of the particles of the aluminum nitride powder, acting to promote densification of the aluminum nitride and to eliminate oxygen being a causative factor that worsens the thermal conductivity of an aluminum nitride sinter, they enable the thermal conductivity of aluminum sinters to be improved.

Yttrium compounds, whose oxygen-eliminating action is particularly pronounced, are preferable rare-earth element compounds. The amount added is preferably 0.01 to 5 wt. %. If less than 0.01 wt. %, producing ultrafine sinters is problematic, along with which the thermal conductivity of the sinters deteriorates. Added amounts in excess of 5 wt. % on the other hand lead to sintering promoter being present at the grain boundaries in an aluminum nitride sinter, and consequently, if the aluminum nitride sinter is employed under a corrosive atmosphere, the sintering promoter present along the grain boundaries gets etched, becoming a source of loosened grains and particles. More preferably the amount of sintering promoter added is 1 wt. % or less. If less than 1 wt. % sintering promoter will no longer be present even at the grain boundary triple points, which improves the corrosion resistance.

To characterize the rare-earth compounds further: oxides, nitrides, fluorides, and stearic oxide compounds may be employed. Among these oxides, being inexpensive and readily obtainable, are preferable. By the same token, stearic oxide compounds are especially suitable since they have a high affinity for organic solvents, and if the aluminum nitride raw-material powder, sintering promoter, etc. are to be mixed together in an organic solvent, the fact that the sintering promoter is a stearic oxide compound will heighten the miscibility.

Next, the aluminum nitride raw-material powder, sintering promoter as a powder, a predetermined volume of solvent, a binder, and further, a dispersing agent or a coalescing agent added as needed, are mixed together. Possible mixing techniques include ball-mill mixing and mixing by ultrasound. Mixing can thus produce a raw material slurry.

The obtained slurry can be molded, and by sintering the molded product, an aluminum nitride sinter can be produced. Co-firing and post-metallization are two possible methods as a way of doing this.

Post-metallization will be described first. Granules are prepared from the slurry by means of a technique such as spray-drying. The granules are inserted into a predetermined mold and subject to press-molding. The pressing pressure therein desirably is 0.1 t/cm² or more. With pressure less than 0.1 t/cm², in most cases sufficient strength in the molded mass cannot be produced, making it liable to break in handling.

Although the density of the molded mass will differ depending on the amount of binder contained and on the amount of sintering promoter added, preferably it is 1.5 g/cm³ or more. Densities less than 1.5 g/cm³ would mean a relatively large distance between particles in the raw-material powder, which would hinder the progress of the sintering. At the same time, the molded mass density preferably is 2.5 g/cm³ or less. Densities of more than 2.5 g/cm³ would make it difficult to eliminate sufficiently the binder from within the molded mass in a degreasing process of a subsequent step. It would consequently prove difficult to produce an ultrafine sinter as described earlier.

Next, heating and degreasing processes are carried out on the molded mass within a non-oxidizing atmosphere. Carrying out the degreasing process under an oxidizing atmosphere such as air would degrade the thermal conductivity of the sinter, because the AlN powder would become superficially oxidized. Preferable non-oxidizing ambient gases are nitrogen and argon. The heating temperature in the degreasing process is preferably 500° C. or more and 1000° C. or less. With temperatures of less than 500° C., surplus carbon is left remaining within the laminate following the degreasing process because the binder cannot sufficiently be eliminated, which interferes with sintering in the subsequent sintering step. On the other hand, at temperatures of more than 1000° C., the ability to eliminate oxygen from the oxidized coating superficially present on the surface of the AlN powder deteriorates, such that the amount of carbon left remaining is too little, degrading the thermal conductivity of the sinter.

The amount of carbon left remaining within the molded mass after the degreasing process is preferably 1.0 wt. % or less. If carbon in excess of 1.0 wt. % remains, it will interfere with the sintering, which would mean that ultrafine sinters could not be produced.

Next, sintering is carried out. The sintering is carried out within a non-oxidizing nitrogen, argon, or like atmosphere, at a temperature of 1700 to 2000° C. Therein the moisture contained in the ambient gas such as nitrogen that is employed is preferably −30° C. or less given in dew point. If it were to contain more moisture than this, the thermal conductivity of the sinter would likely be degraded, because the AlN would react with the moisture within the ambient gas during sintering and form nitrides. Another preferable condition is that the volume of oxygen within the ambient gas be 0.001 vol. % or less. A larger volume of oxygen would lead to a likelihood that the AlN would oxidize, impairing the sinter thermal conductivity.

As another condition during sintering, the jig employed is suitably a boron nitride (BN) molded part. Inasmuch as the jig as a BN molded part will be sufficiently heat resistant against the sintering temperatures, and superficially will have solid lubricity, when the laminate contracts during sintering, friction between the jig and the laminate will be lessened, which will enable sinters to be produced with little distortion.

The obtained sinter is subjected to processing according to requirements. In cases where a conductive paste is to be screen-printed onto the sinter in a succeeding step, the surface roughness is preferably 5 □m or less in Ra. If over 5 □m, in screen printing to form circuits, defects such as blotting or pinholes in the pattern are liable to arise. More suitable is a surface roughness of 1 □m or less in Ra.

In polishing to the abovementioned surface roughness, although cases in which both sides of the sinter are screen printed are a matter of course, even in cases where screen printing is effected on one side only the polishing process is best carried out on the face on the side opposite the screen-printing face. This is because polishing only the screen-printing face would mean that during screen printing, the sinter would be supported on the unpolished face, and in that situation burrs and debris would be present on the unpolished face, destabilizing the fixedness of the sinter such that the circuit pattern by the screen printing might not be drawn well.

Furthermore, at this point the thickness uniformity (parallelism) between the processed faces is preferably 0.5 mm or less. Thickness uniformity exceeding 0.5 mm can lead to large fluctuations in the thickness of the conductive paste during screen printing. Particularly suitable is a thickness uniformity of 0.1 mm or less. Another preferable condition is that the planarity of the screen-printing face be 0.5 mm or less. If the planarity exceeds 0.5 mm, in that case too there can be large fluctuations in the thickness of the conductive paste during screen printing. Particularly suitable is a planarity of 0.1 mm or less.

Screen printing is used to spread a conductive paste and form the electrical circuits onto a sinter having undergone the polishing process. The conductive paste can be obtained by mixing together with a metal powder an oxidized powder, a binder, and a solvent according to requirements. The metal powder is preferably tungsten, molybdenum or tantalum, since their thermal expansion coefficients match those of ceramics.

Adding the oxidized powder to the conductive paste is also to enhance the strength with which it bonds to AlN. The oxidized powder preferably is an oxide of Group IIa or Group IIIa elements, or is Al₂O₃, SiO₂, or a like oxide. Yttrium oxide is especially preferable because it has very good wettability with AlN. The amount of such oxides added is preferably 0.1 to 30 wt. %. If the amount is less than 0.1 wt. %, the bonding strength between AlN and the metal layer being the circuit that has been formed deteriorates. On the other hand, amounts in excess of 30 wt. % make the electrical resistance of the circuit metal layer high.

The thickness of the conductive paste is preferably 5 □m or more and 100 □m or less in terms of it post-drying thickness. If the thickness were less than 5 □m the electrical resistance would be too high and the bonding strength decline. Likewise, if in excess of 100 □m the bonding strength would deteriorate in that case too.

Also preferable is that in the patterns for the circuits that are formed, in the case of the heater circuit (resistive heating element circuit), the pattern spacing be 0.1 mm or more. With a spacing of less than 0.1 mm, shorting will occur when current flows in the resistive heating element and, depending on the applied voltage and the temperature, leakage current is generated. Particularly in cases where the circuit is employed at temperatures of 500° C. or more, the pattern spacing preferably should be 1 mm or more; more preferable still is that it be 3 mm or more.

After the conductive paste is degreased, baking follows. Degreasing is carried out within a non-oxidizing nitrogen, argon, or like atmosphere. The degreasing temperature is preferably 500° C. or more. At less than 500° C., elimination of the binder from the conductive paste is inadequate, leaving behind carbon in the metal layer that during baking will form carbides with the metal and consequently raise the electrical resistance of the metal layer.

The baking is suitably done within a non-oxidizing nitrogen, argon, or like atmosphere at a temperature of 1500° C. or more. At temperatures of less than 1500° C., the post-baking electrical resistance of the metal layer turns out too high because the baking of the metal powder within the paste does not proceed to the grain growth stage. A further baking parameter is that the baking temperature should not surpass the firing temperature of the ceramic produced. If the conductive paste is baked at a temperature beyond the firing temperature of the ceramic, dispersive volatilization of the sintering promoter incorporated within the ceramic sets in, and moreover, grain growth in the metal powder within the conductive paste is accelerated, impairing the bonding strength between the ceramic and the metal layer.

In order to ensure that the metal layer is electrically isolated, an insulative coating can be formed on the metal layer. Preferably the insulative coating substance is the same substance as the ceramic on which the metal layer is formed. Problems such as post-sintering warpage arising from the difference in thermal expansion coefficient will occur if the ceramic and insulative coating substances differ significantly. For example, in a case where the ceramic is AlN, a predetermined amount of an oxide/carbide of a Group IIa element or a Group IIIa element can be added to and mixed together with AlN powder, a binder and a solvent added and the mixture rendered into a paste, and the paste can be screen-printed to spread it onto the metal layer.

In that case, the amount of sintering promoter added preferably is 0.01 wt. % or more. With an amount less than 0.01 wt. % the insulative coating does not densify, making it difficult to secure electrical isolation of the metal layer. It is further preferable that the amount of sintering promoter not exceed 20 wt. %. Surpassing 30 wt. % leads to excess sintering promoter invading the metal layer, which can end up altering the metal-layer electrical resistance. Although not particularly limited, the spreading thickness preferably is 5 □m or more. This is because securing electrical isolation proves to be problematic at less than 5 □m.

Further according to the present method, the ceramic as substrates can be laminated according to requirements. Lamination may be done via an adhesive agent. The adhesive agent—being a compound of Group IIa or Group IIIa elements, and a binder and solvent, added to an aluminum oxide powder or aluminum nitride powder and made into a paste—is spread onto the bonding surface by a technique such as screen printing. The thickness of the applied adhesive agent is not particularly restricted, but preferably is 5 □m or more. Bonding defects such as pinholes and bonding irregularities are liable to arise in the adhesive layer with thicknesses of less than 5 □m.

The ceramic substrates onto which the adhesive agent has been spread are degreased within a non-oxidizing atmosphere at a temperature of 500° C. or more. The ceramic substrates are thereafter bonded to one another by stacking the ceramic substrates together, applying a predetermined load to the stack, and heating it within a non-oxidizing atmosphere. The load preferably is 0.05 kg/cm² or more. With loads of less than 0.05 kg/cm² sufficient adhesive strength will not be obtained, and otherwise defects in the joint will likely occur.

Although the heating temperature for bonding is not particularly restricted as long as it is a temperature at which the ceramic substrates adequately bond to one another via the adhesive layers, preferably it is 1500° C. or more. At less than 1500° C. adequate adhesive strength proves difficult to gain, such that defects in the bond are liable to arise. Nitrogen or argon is preferably employed for the non-oxidizing atmosphere during the degreasing and boding just discussed.

A ceramic laminated sinter that serves as a wafer holder thus can be produced as in the foregoing. As far as the electrical circuits are concerned, it should be understood that if they are heater circuits for example, then a molybdenum coil can be utilized—and in the electrostatic-chuck electrode and RF power-generating electrode circuit cases, molybdenum or tungsten mesh can be—without employing conductive paste.

In this case, the molybdenum coil or the mesh can be built into the AlN raw-material powder, and the wafer holder can be fabricated by hot pressing. While the temperature and atmosphere in the hot press may be on par with the AlN sintering temperature and atmosphere, the hot press desirably applies a pressure of 10 kg/cm² or more. With pressure of less than 10 kg/cm², the wafer holder might not exhibit its capabilities, because gaps arise between the AlN and the molybdenum coil or the mesh.

Co-firing will now be described. The earlier-described raw-material slurry is molded into a sheet by doctor blading. The sheet-molding parameters are not particularly limited, but the post-drying thickness of the sheet advisably is 3 mm or less. The sheet thickness surpassing 3 mm leads to large shrinkage in the drying slurry, raising the probability that fissures will be generated in the sheet.

A metal layer of predetermined form that serves as an electrical circuit is formed onto the abovementioned sheet using a technique such as screen printing to spread onto it a conductive paste. The conductive paste utilized can be the same as that which was descried under the post-metallization method. Nevertheless, not adding an oxidized powder to the conductive paste does not hinder the co-firing method.

Subsequently, sheets that have undergone circuit formation are laminated with sheets that have not. Lamination is by setting the sheets each into position to stack them together. Therein, according to requirements, a solvent is spread on between sheets. In the stacked state, the sheets are heated as may be necessary. In cases where the stack is heated, the heating temperature is preferably 150° C. or less. Heating to temperatures in excess of this greatly deforms the laminated sheets. Pressure is then applied to the stacked-together sheets to unitize them. The applied pressure is preferably within a range of from 1 to 100 MPa. At pressures less than 1 MPa, the sheets are not adequately unitized and can peel apart during subsequent processes. Likewise, if pressure in excess of 100 MPa is applied, the extent to which the sheets deform becomes too great.

This laminate undergoes a degreasing process as well as sintering, in the same way was with the post-metallization method described earlier. Parameters such as the temperature in degreasing and sintering and the amount of carbon are the same as with post-metallization. In the previously described screen printing of a conductive paste onto sheets, a wafer holder having a plurality of electrical circuits can be readily fabricated by printing heater circuits, electrostatic-chuck electrode circuits, etc. respectively onto a plurality of sheets and laminating them. In this way a ceramic laminated sinter that serves as a wafer holder can be produced.

The obtained ceramic laminated sinter is subject to processing according to requirements. Routinely with semiconductor manufacturing devices, in the sintered state the ceramic laminated sinter often cannot be gotten into the precision demanded. The planarity of the wafer-carrying surface as an example of processing precision is preferably 0.5 mm or less; moreover 0.1 mm or less is particularly preferable. The planarity surpassing 0.5 mm is apt to give rise to gaps between the wafer and the wafer holder, keeping the heat of the wafer holder from being uniformly transmitted to the wafer and making likely the generation of temperature irregularities in the wafer.

A further preferable condition is that the surface roughness of the wafer-carrying surface be 5 □m in Ra. If the roughness is over 5 □m in Ra, grains loosened from the AlN due to friction between the wafer holder and the wafer can grow numerous. Particles loosened in that case become contaminants that have a negative effect on processes, such as film deposition and etching, on the wafer. Furthermore, then, a surface roughness of 1 □m or less in Ra is ideal.

A wafer holder base part can thus be fabricated as in the foregoing. Furthermore, a shaft is attached to the wafer holder. Although the shaft substance is not particularly limited as long as its thermal expansion coefficient is not appreciably different from that of the wafer-holder ceramic, the difference in thermal expansion coefficient between the shaft substance and the wafer holder preferably is 5×10⁻⁶ K or less.

If the difference in thermal expansion coefficient exceeds 5×10⁻⁶ K, cracks can arise adjacent the joint between the wafer holder and the shaft when it is being attached; but even if cracks do not arise when the two are joined, splitting and cracking can occur in the joint in that it is put through heating cycling in the course of being repeatedly used. For cases in which the wafer holder is AlN, for example, the shaft substance is optimally AlN; but silicon nitride, silicon carbide, or mullite can be used.

Mounting is joining via an adhesive layer. The adhesive layer constituents preferably are composed of AlN and Al₂O₃, as well as rare-earth oxides. These constituents are preferable because of their favorable wettability with ceramics such as the AlN that is the substance of the wafer holder and the shaft, which makes the joint strength relatively high, and readily produces a gastight joint surface.

The planarity of the respective joining faces of the shaft and wafer holder to be joined preferably is 0.5 mm or less. Planarity greater than this makes gaps liable to occur in the joining faces, impeding the production of a joint having adequate gastightness. A planarity of 0.1 mm or less is more suitable. Here, still more suitable is a planarity of the wafer holder joining faces of 0.02 mm or less. Likewise, the surface of the respective joining faces preferably is 5 □m or less in Ra. Surface roughness exceeding this would then also mean that gaps are liable to occur in the joining faces. A surface roughness of 1 □m or less in Ra is still more suitable.

Subsequently, electrodes are attached to the wafer holder. The attaching can be done according to publicly known techniques. For example, the side of the wafer holder opposite its wafer-retaining face, may be spot faced through to the electrical circuits, and metallization carried out on the circuit, or without metallizing, electrodes of molybdenum, tungsten, etc. may be connected to it directly using an active metal brazing material. The electrodes can thereafter be plated as needed to improve their resistance to oxidation. In this way, a wafer holder for semiconductor manufacturing devices can be fabricated.

Moreover, where film deposition is done onto wafers on a wafer holder that is set up in semiconductor manufacturing equipment and in which according to the present invention an electrode circuit for generating high-frequency RF is formed, semiconductor manufacturing equipment wherein film is deposited uniformly onto wafers, and the generation of particles is slight can be gained.

Embodiments

Embodiment 1

99 parts by weight aluminum nitride powder and 1 part by weight Y₂O₃ powder were mixed and blended with 10 parts by weight polyvinyl butyral as a binder and 5 parts by weight dibutyl phthalate as a solvent, and doctor-bladed into green sheets 430 mm in diameter and 1.3 mm in thickness. Here, an aluminum nitride powder having a mean particle diameter of 0.6 □m and a specific surface area of 3.4 m²/g was utilized. In addition, a tungsten paste was prepared utilizing 100 parts by weight of a tungsten powder whose mean particle diameter was 2.0 □m; and per that, 1 part by weight Y₂O₃ and 5 parts by weight ethyl cellulose, being a binder; and butyl Carbitol™ as a solvent. A pot mill and a triple-roller mill were used for mixing. This tungsten paste was formed into a pattern for an electrode circuit for generating high-frequency RF by screen-printing the paste onto the green sheets. Items in which the diameter of the RF-generating electrode circuit was varied as set forth in Table I were fabricated. In addition, a heater circuit pattern was formed onto separate green sheets.

Pluralities of separate green sheets of thickness 1.3 mm were laminated onto the green sheets printed with the heater circuit, and finally laminates with the green sheet on which an RF-generating electrode circuit was printed were fabricated. Lamination was carried out by stacking the sheets in place in a mold, and thermopressing 2 minutes in a press at a pressure of 10 MPa while maintaining 50° C. heat. The laminates were thereafter degreased within a nitrogen atmosphere at 600° C., and sintered within a nitrogen atmosphere under time and temperature conditions of 3 hours and 1800° C., whereby wafer holders were produced. Here, after sintering a polishing process was performed on the wafer-retaining face so that it would be 1 □m or less in Ra, and on the shaft-joining face so that it would be 5 □m or less in Ra. The wafer holders were also processed to true their outer diameter. The dimensions of the post-processing wafer holders were 350 mm outside diameter and 20 mm thickness. Also, the distance separating the wafer-carrying surface from the RF-generating electrode circuit was 1 mm.

The RF-generating electrode circuits and heater circuits in the wafer holders were partially exposed by spot-facing through the surface in three locations on the side opposite the wafer-retaining face, up to the RF-generating electrode circuit and heater circuit. Electrodes made of tungsten were joined directly to the exposed portions of the RF-generating electrode circuits and heater circuits utilizing an active metal brazing material. Wafer holders thus fabricated, in which the RF-generating electrode circuits differed in diameter, were set up within semiconductor manufacturing equipment.

Silicon wafers 300 mm in diameter were set in place atop the wafer holders, and the wafer holders were heated by passing current through the heater-circuit electrodes. Next plasma was generated by introducing WF₆, SiH₄ and H4 into the process chamber as reaction gases and applying high-frequency power to the electrodes for the RF-generating electrode circuits, whereby a tungsten film was deposited onto the silicon wafers.

The thickness of the tungsten films deposited was measured with an X-ray fluorescence thickness gauge, and the results are entered in Table I—as “good” where film-thickness distribution was uniform; as “fair” where the film-thickness distribution was comparatively large, but would be tolerable for working applications; and as “NG” (no good) where the film-thickness distribution was so great that the wafers would be unusable for practical purposes. With regard to film formed onto the wafer-carrying surface outward of the wafers, tabulated and also entered in Table I are: as “good,” wafer holders on which film did not form, or almost did not form, at all; as “fair,” those on which something of a deposited film was recognizable; and as “NG,” those on which a film was deposited to the same extent as on the wafer. The proportions that the diameter of the RF-generating electrode circuits are of the diameter of the carried silicon wafers, and the distances between the periphery of the RF power-generating electrode circuit and the periphery of the wafer holder, are also set forth in Table I.

TABLE I

| | Electrode | | Separation | | Off-wafer |
|---|---|---|---|---|---|
| | dia. | Proportion | from perimeter | Thickness | film |
| No. | (mm) | (%) | (mm) | distribution | deposition |
| 1 | 240 | 80 | 55 | NG | Good |
| 2 | 255 | 85 | 47.5 | NG | Good |
| 3 | 270 | 90 | 40.0 | Fair | Good |
| 4 | 285 | 95 | 32.5 | Fair | Good |
| 5 | 300 | 100 | 25 | Good | Good |
| 6 | 330 | 110 | 10 | Good | Good |
| 7 | 345 | 115 | 2.5 | Good | Good |
| 8 | 348 | 116 | 1.0 | Good | Good |
| 9 | 349 | 116.3 | 0.5 | Good | Fair |
| 10 | 349.5 | 116.5 | 0.25 | Good | NG |

As is evident from the table, by making the diameter of the RF-generating electrode circuits 90% or more of the diameter of the wafers, uniform films whose thickness distribution is within range tolerable for working applications are deposited. What is more, films of even more uniform thickness distribution are deposited if the RF electrode circuit diameter is made the wafer diameter or greater. Still further, making the distance by which the wafer-holder surface apart from the wafer-retaining face is separated from the RF-generating electrode circuit longer than the distance separating the RF-generating electrode circuit from the wafer-retaining face keeps the deposition of film onto the region of the wafer-retaining face outward of the wafer under control.

Embodiment 2

An aluminum nitride slurry of composition likewise as in Embodiment 1 was prepared utilizing aluminum nitride powder and Y₂O₃ powder, and polyvinyl butyral as a binder and dibutyl phthalate, in the same manner as in Embodiment 1. Granules were prepared from the slurry, utilizing a spray drier. The granules were set into a mold, embedded with a mesh made of molybdenum (Mo), and hot-pressed to produce AlN sinters of 360 mm outer diameter, 5 mm thickness. The Mo mesh, which was the RF-generating electrode circuit, was used in the diameters set forth in Table II. In addition, an AlN sinter of 1 mm thickness was prepared and a heater circuit was formed by screen printing onto the sinter the tungsten paste utilized in Embodiment 1. Also, a base material for the wafer holders was produced by preparing separate AlN sinters of 1 mm thickness and joining them together with Al₂O₃—Y₂O₃—AlN as a bonding agent. The top and bottom sides as will as the perimeter were processed to produce 350 mm outer diameter, 20 mm thickness wafer holders. Here, the distanced separating the Mo mesh being the RF-generating electrode circuit from the wafer-retaining face was 1 mm.

These wafer holders were set up in semiconductor manufacturing equipment as was the case with Embodiment 1, and deposited-film evaluations were made in the same manner as in Embodiment 1. The results are set forth in Table II.

TABLE II

| | Electrode | | Separation | | Off-wafer |
|---|---|---|---|---|---|
| | dia. | Proportion | from perimeter | Thickness | film |
| No. | (mm) | (%) | (mm) | distribution | deposition |
| 11 | 240 | 80 | 55 | NG | Good |
| 12 | 255 | 85 | 47.5 | NG | Good |
| 13 | 270 | 90 | 40.0 | Fair | Good |
| 14 | 285 | 95 | 32.5 | Fair | Good |
| 15 | 300 | 100 | 25 | Good | Good |
| 16 | 330 | 110 | 10 | Good | Good |
| 17 | 345 | 115 | 2.5 | Good | Good |
| 18 | 348 | 116 | 1.0 | Good | Good |
| 19 | 349 | 116.3 | 0.5 | Good | Fair |
| 20 | 349.5 | 116.5 | 0.25 | Good | NG |

As is evident from the table, the same effects with the electrode circuit outer diameter and the distance relationship between the electrode circuit and the wafer-retaining face also proved to be true using Mo mesh for the RF-generating electrode circuit.

According to the present invention as given in the foregoing, making the diameter of the RF-generating electrode circuits a size that is 90% or more of the wafer diameter enables wafer holders and semiconductor manufacturing equipment with which films whose thickness distribution is uniform are deposited to be realized. Likewise, rendering the distance between the periphery of the RF-generating electrode circuit and the periphery of the wafer holder longer than the distance separating the electrode circuit from the wafer-carrying surface enables the realization of wafer holders, and semiconductor manufacturing equipment in which they are installed, wherein the generation of particles is slight.

Only selected embodiments have been chosen to illustrate the present invention. To those skilled in the art, however, it will be apparent from the foregoing disclosure that various changes and modifications can be made herein without departing from the scope of the invention as defined in the appended claims. Furthermore, the foregoing description of the embodiments according to the present invention is provided for illustration only, and not for limiting the invention as defined by the appended claims and their equivalents.

What is claimed is:

1. A wafer holder for semiconductor manufacturing equipment, the wafer holder having a surface for carrying wafers and comprising:
a high-frequency RF power-generating electrode circuit round in form, built into the wafer holder, the electrode circuit diameter being 90% or more of the diameter of wafers that the wafer holder carries.

2. A wafer holder for semiconductor manufacturing equipment, the wafer holder having a surface for carrying wafers and comprising:
a high-frequency RF power-generating electrode circuit, built into the wafer holder, the distance between the electrode circuit peripherally and the wafer holder peripherally being longer than the distance separating the electrode circuit from the wafer-carrying surface.

3. A wafer holder as set forth in claim 1, wherein the distance between the periphery of the high-frequency RF power-generating electrode circuit built into the wafer holder and the periphery of the wafer holder is longer than the distance separating said electrode circuit from the wafer-carrying surface.

4. Semiconductor manufacturing equipment wherein the wafer holder set forth in claim 2 is installed.

5. Semiconductor manufacturing equipment wherein the wafer holder set forth in claim 3 is installed.
